(19) United States
(12) Patent Application Publication
(10) Pub. No.: US 2022/0058359 A1
(43) Pub. Date: Feb. 24, 2022

(54) PATTERNED FINGERPRINT SENSING MODULE AND MANUFACTURING METHOD THEREOF

(71) Applicant: ELAN MICROELECTRONICS CORPORATION, Hsinchu (TW)

(72) Inventor: Yu-Kai LIN, Hsinchu City (TW)

(73) Assignee: ELAN MICROELECTRONICS CORPORATION, Hsinchu (TW)

(21) Appl. No.: 17/371,156

(22) Filed: Jul. 9, 2021

(30) Foreign Application Priority Data
Aug. 24, 2020 (TW) 109128847

(51) Int. Cl. G06K 9/00; G06K 9/20; B32B 7/12; B32B 37/12; B32B 37/18

(52) U.S. Cl. CPC G06K 9/0002; G06K 9/209; B32B 2457/00; B32B 37/12; B32B 37/18; B32B 7/12

(57) ABSTRACT

A fingerprint sensing module has a fingerprint sensor and a cover. The main color layer and the pattern layer are arranged between the cover and the fingerprint sensor. The pattern layer constitutes a predetermined pattern that is used to present the pattern of the button. The both sides of the main color layer are flush with both sides of the pattern layer, so that the capacitance variations in the corresponding pattern layer and the main color layer pass through the medium with the same thickness, and have an approximate capacitance variation mode. Thus, the sensed fingerprint image truly reflect the detected fingerprint image without being affected by the preset pattern, and a pattern layer with a certain thickness is used to enhance the color saturation presented by the predetermined pattern.

### CROSS-REFERENCE TO RELATED APPLICATIONS

This application is based upon and claims priority under 35 U.S.C. 119 from Taiwan Patent Application No. 109128847filed on Aug. 24, 2020, which is hereby specifically incorporated herein by this reference thereto.

### BACKGROUND OF THE INVENTION

### 1. Field of the Invention

The present invention relates to a fingerprint sensing module and a manufacturing method thereof, especially to a fingerprint sensing module mounted in an electronic device for sensing a user's fingerprint.

### 2. Description of the Prior Arts

Due to the popularity of the portable electronic devices, the probability of users bringing portable electronic devices to various occasions is greatly increased. It also increases the proportion of users storing various confidential or important information in portable electronic devices so that the user authentication mechanism of the portable electronic devices has received more and more attention. The traditional portable electronic device uses a password as a user authentication mechanism, but the password has a higher chance of being cracked or being spied on, so the protection is low. Therefore, biometric identification is gradually used as a user authentication mechanism, which is difficult to crack and cannot be stolen from plying eyes. Therefore, the biometric identification is gradually becoming an important accessory in the portable electronic devices. Among various biometric identification methods, the fingerprint identification is the current mainstream. As a result, a fingerprint sensing module is installed in the portable electronic device to recognize the user's fingerprint, and the sensing result is used as a user authentication mechanism.

With reference to FIGS. 9 to 11, since the portable electronic device 80 requires lightness, thinness and shortness, the fingerprint sensing module 90 in accordance with the prior art is integrated into one button 81. For example, a power button 81 as shown in FIG. 10. The fingerprint sensing module 90 has a cover 91. One side of the cover 91 is coated with a pattern layer 92. The pattern layer 92 shows the patterns representing the button 81 such as a power pattern. A main color layer 93 is coated on the cover 91, which is coated on the same side of the pattern layer 92, and covers the pattern layer 92. Since the pattern layer 92 has a certain thickness, the main color layer 93 forms a protrusion 931 where the pattern layer 92 corresponds to when the main color layer 93 is coated. The fingerprint sensor 94 is disposed on a bottom side of the pattern layer 92 through a bottom adhesive layer 95.

With reference to FIGS. 12 and 13, when a finger 70 contacts the cover 91, the fingerprint sensor 94 detects the change in capacitance resulted from the fingerprint of the finger 70. Due to the pattern layer 92 and protrusions 931, the medium corresponding to the pattern layer 92 is uneven and the thickness of the medium is different from other regions. Then the resulting capacitance change is significantly different at the corresponding pattern layer 92 from the rest of the regions. Therefore, the captured fingerprint image shows the afterimage of the corresponding pattern, which further affects the accuracy of fingerprint sensing.

Furthermore, due to the aforementioned image sticking problem, the thickness of the pattern layer 92 is generally thinner than that of the main color layer 93 so that the shielding effect is poor. Then the pattern to be presented by the pattern layer 92 is affected by the color of the main color layer 93 and the color saturation is not good.

### SUMMARY OF THE INVENTION

To overcome the shortcomings, the present invention provides a patterned fingerprint sensing module and manufacturing method thereof to mitigate or to obviate the aforementioned problems.

To achieve the main objective, a patterned fingerprint sensing module is provided. The patterned fingerprint sensing module comprises a fingerprint sensor having a sensing array to detect a fingerprint; a cover disposed on a top of the fingerprint sensor corresponding to the sensing array; a main color layer disposed between the cover and the fingerprint sensor and having a first side and a second side; and a pattern layer disposed between the cover and the fingerprint sensor, disposed on the same layer with the main color layer, constituting a predetermined pattern and having a first side and a second side, wherein a color of the main color layer is different from a color of the pattern layer, the first side of the main color layer is flush with the first side of the pattern layer, and the second side of the main color layer is flush with the second side of the pattern layer.

In another aspect, a manufacturing method of a patterned fingerprint sensing module is provided and comprises steps of: providing a cover with a first side and a second side; disposing a main color layer and a pattern layer on the first side of the cover wherein, the main color layer and the pattern layer are disposed on the same layer, the pattern layer constitutes a predetermined pattern, a first side of the main color layer is flush with a first side of the pattern layer, a second side of the main color layer is flush with a second side of the pattern layer, the second side of the main color layer and the second side of the pattern layer correspond to the first side of the cover; and disposing a fingerprint sensor on the first side of the main color layer and the first side of the pattern layer.

Other objectives, advantages and novel features of the invention will become more apparent from the following detailed description when taken in conjunction with the accompanying drawings.

### BRIEF DESCRIPTION OF THE DRAWINGS

FIG. 1 is an illustrative side view in partial section of a fingerprint sensing module in accordance with the present invention, wherein the fingerprint sensor is shown by broken lines to demonstrate a part of the fingerprint sensor;

FIG. 2 is an operational side view in partial section of the fingerprint sensing module in FIG. 1 with a finger;

FIG. 3 is a chart to show the relationship between the sensing capacitances and the coordinates when using the fingerprint sensing module in FIG. 1;

FIG. 4 is an illustrative side view in partial section of another embodiment of a fingerprint sensing module in accordance with the present invention;

FIGS. 5 to 8 are side views in partial sections showing the manufacturing steps of the fingerprint sensing module in FIG. 4;

FIG. 9 is a perspective view of a portable electronic device;

FIG. 10 is an enlarged perspective view of a part of the portable electronic device in FIG. 9;

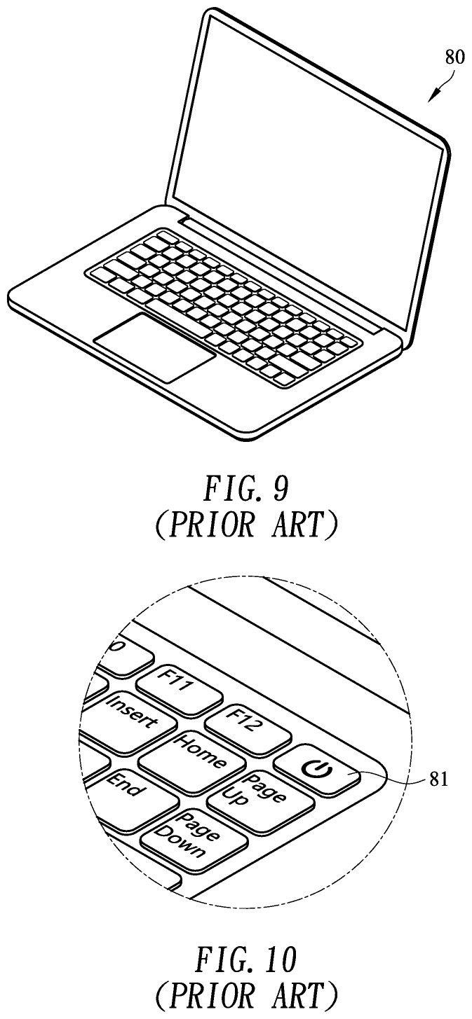

FIG. 11 is an illustrative side view in partial section of a conventional fingerprint sensing module in accordance with the prior art;

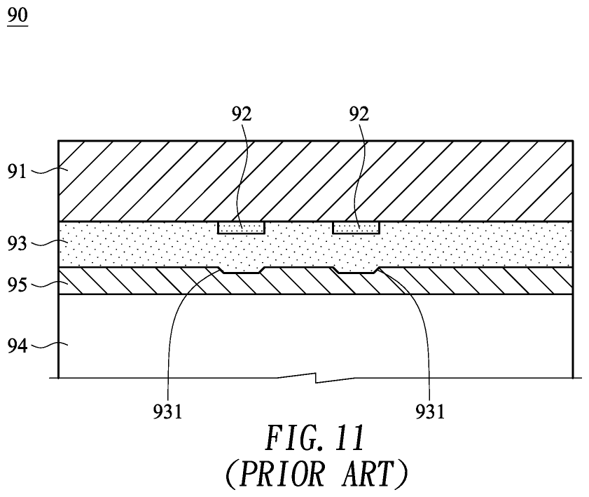

FIG. 12 is an operational side view in partial section of the conventional fingerprint sensing module in FIG. 11 with a finger; and

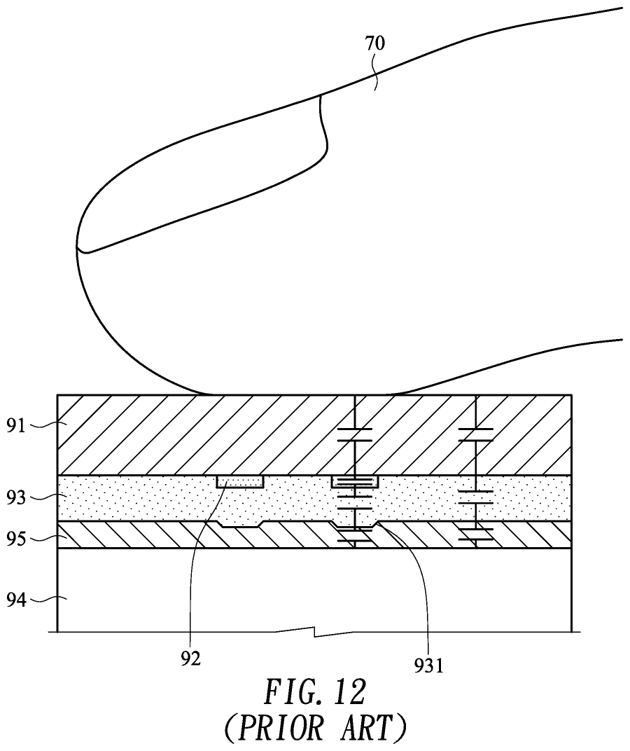

FIG. 13 is a chart to show the relationship between the sensing capacitances and the coordinates when using the conventional fingerprint sensing module in FIG. 11.

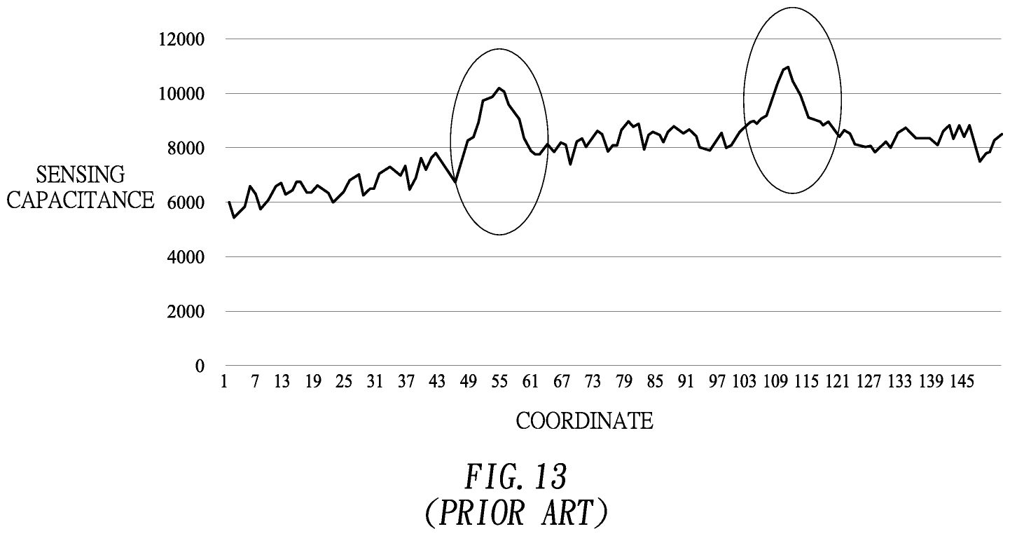

### DETAILED DESCRIPTION OF THE EMBODIMENTS

With reference to the attached drawings, the present invention is described by means of the embodiment(s) below where the attached drawings are simplified for illustration purposes only to illustrate the structures or methods of the present invention by describing the relationships between the components and assembly in the present invention. Therefore, the components shown in the figures are not expressed with the actual numbers, actual shapes, actual dimensions, nor with the actual ratio. Some of the dimensions or dimension ratios have been enlarged or simplified to provide a better illustration. The actual numbers, actual shapes, or actual dimension ratios can be selectively designed and disposed and the detail component layouts may be more complicated.

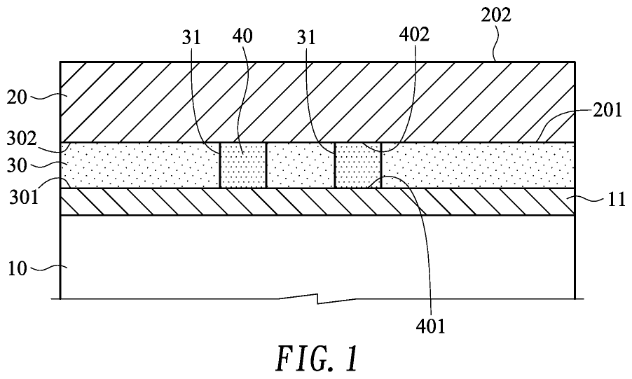

With reference to FIG. 1, a fingerprint sensing module with patterns in accordance with the present invention comprises a fingerprint sensor 10, a cover 20, a main color layer 30 and a pattern layer 40.

The fingerprint sensor 10 is used to detect the fingerprints and has a sensing array. The sensing array detects the variation of the capacitance resulting from the fingerprints to obtain the fingerprint images.

The cover 20 corresponds to the sensing array of the fingerprint sensor 10 and is disposed on a top surface of the fingerprint sensor 10. The cover 20 has a first side 201 and a second side 202. The first side 201 of the cover 20 faces to the fingerprint sensor 10. In one embodiment, the cover 20 is transparent or translucent.

The main color layer 30 is disposed between the cover 20 and the fingerprint sensor 10 and has at least one orifice 31 formed therethrough. The at least one orifice 31 forms a predetermined pattern to be presented by the fingerprint sensing module but the patterns of present invention are not limited thereto. For example, if the fingerprint sensing module constitutes a power button, the predetermined pattern shows a power pattern. The main color layer 30 has a first side 301 and a second side 302. The second side 302 of the main color layer 30 is attached to the first side 201 of the cover 20. The first side 301 of the main color layer 301 faces to the fingerprint sensor 10. In one embodiment, the fingerprint sensor 10 is attached to the first side 301 of the main color layer 30 via an adhesive layer 11.

The pattern layer 40 is disposed in the orifices 31 of the main color layer 30. The color of the pattern layer 40 is different from the color of the main color layer 30, so that the pattern layer 40 having different color presents the predetermined pattern in the orifices 31 of the main color layer 30. The pattern layer 40 has a first side 401 and a second side 402. The first side 401 of the pattern layer 40 is flush with the first side 301 of the main color layer 30. The second side 402 of the pattern layer 40 is flush with the second side 302 of the main color layer 30.

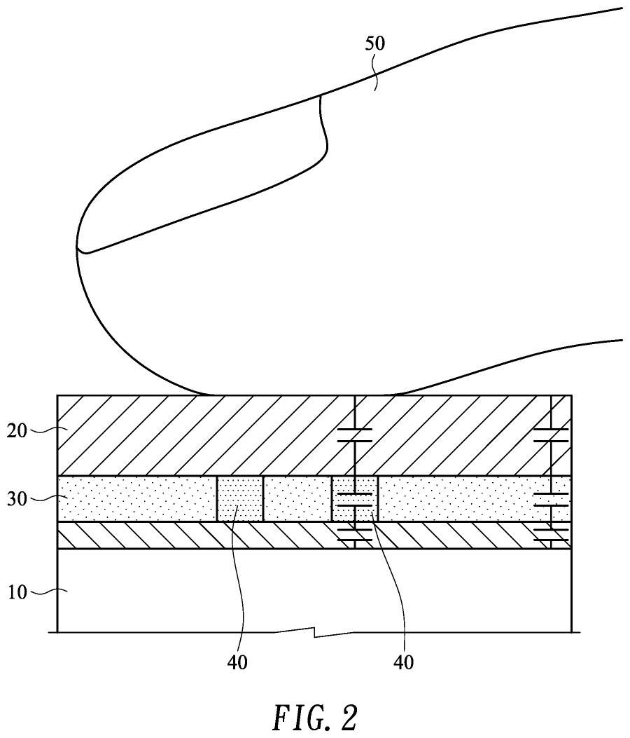

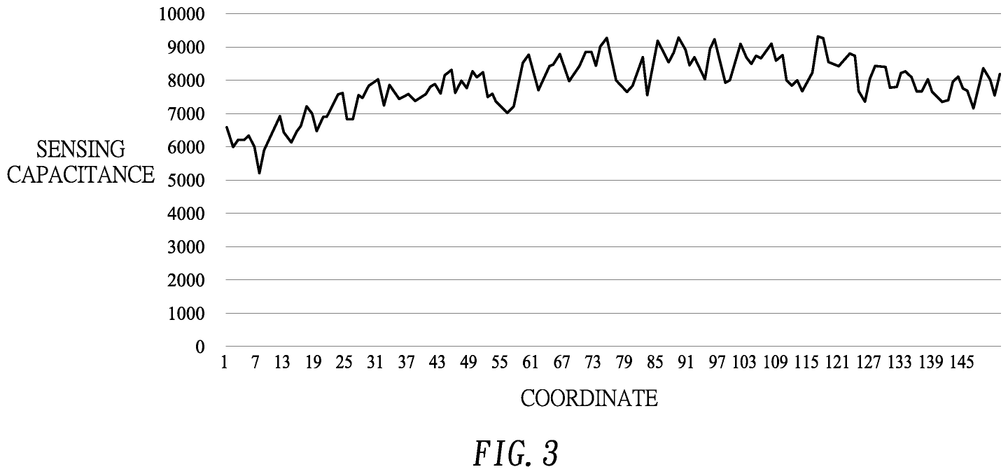

With reference to FIG. 2, a finger 50 contacts the second side 202 of the cover 20 to execute fingerprint sensing. The fingerprint sensor 10 detects the variation of the capacitance resulting from the contact of the finger 50. Since the first side 401 and the second side 402 of the pattern layer 40 are flush respectively with the first side 301 and the second side 302 of the main color layer 30, the pattern layer 40 is as thick as the main color layer 30. Thus, the thicknesses of the mediums corresponding to the pattern layer 40 and the main color layer 30 are the same. As shown in FIG. 3, the capacitance change sensed by the fingerprint sensor 10 only changes to the fingerprint of the finger 50, and is not affected by the position of the pattern layer 40. Then the fingerprint image obtained is not be imprinted with a residual image similar to the predetermined pattern.

Moreover, the closer the dielectric constant of the pattern layer 40 and the main color layer 30 is, the more the capacitance change generated by the pattern layer 40 is similar to the capacitance variation phenomenon generated by the main color layer 30. In one embodiment, the difference between the dielectric constant of the pattern layer 40 and the dielectric constant of the main color layer 30 is between -2 and +2. In one embodiment, the pattern layer 40 and the main color layer 30 are inks of the same material but different colors, so the dielectric constants are close.

Further, since the pattern layer 40 is not covered by the main color layer 30 and is as thick as the main color layer 30, the color of the pattern layer 40 itself is fully presented without being affected by the main color layer 30. Therefore, the color selection of the pattern layer 40 is no longer limited to the main color layer 30, and the color saturation presented by the predetermined pattern is effectively improved.

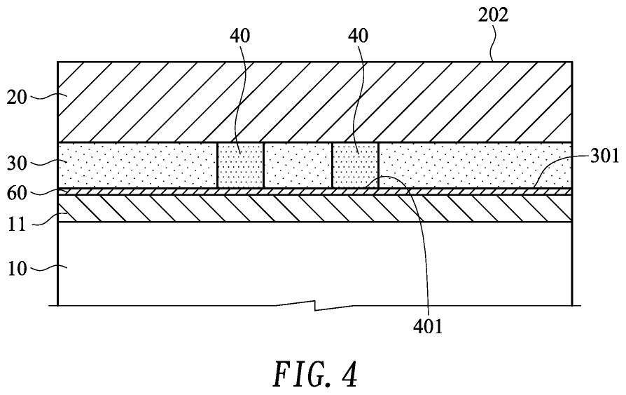

With reference to FIG. 4, in one embodiment, a bottom layer 60 is disposed between the fingerprint sensor 10 and the main color layer 30. Further, the bottom layer 60 is disposed between the adhesive layer 11 and the main color layer 30. The bottom layer 60 is disposed on the first side 301 of the main color layer 30 and the first side 401 of the main color layer 40. When the main color layer 30 and the pattern layer 40 are disposed, the first side 301 of the main color layer 30 and the first side 401 of the pattern layer 401 may be slightly uneven. Therefore, the bottom layer 60 is used to complement the flatness of the first side surface 301 of the main color layer 30 and the first side surface 401 of the pattern layer 40.

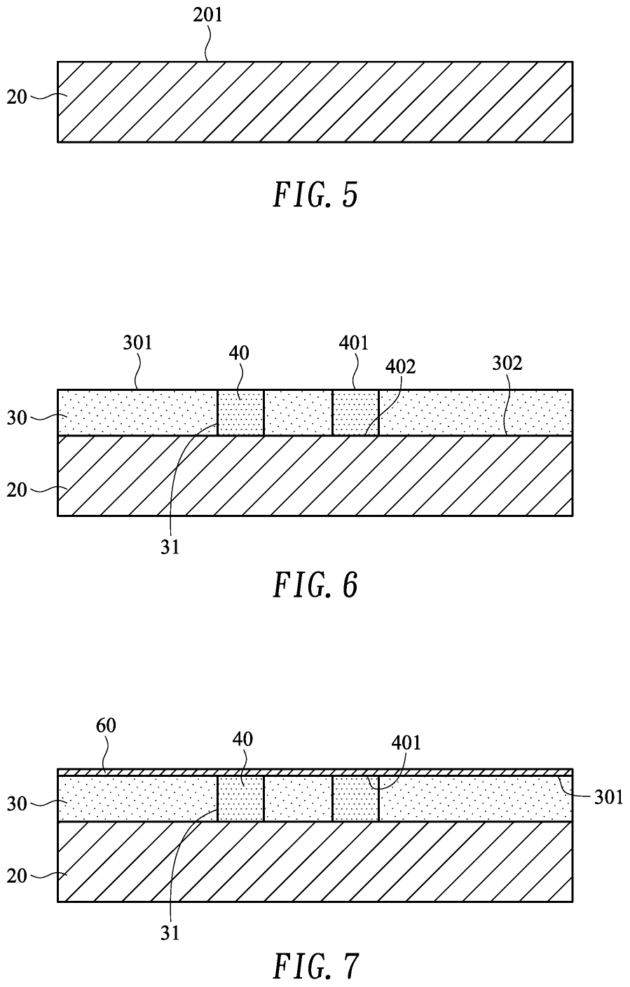

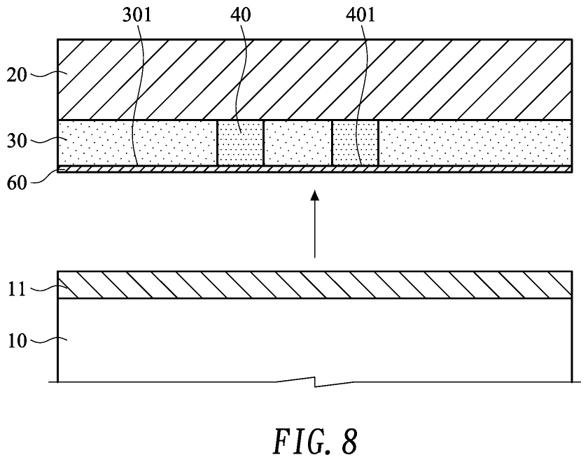

With reference to FIGS. 5 to 9, a manufacturing method of a patterned fingerprint sensing module in accordance with the present invention comprises following steps. A cover 20 is provided as shown in FIG. 5. A main color layer 30 and a pattern layer 40 are disposed on the first side 201 of the cover 20 as shown in FIG. 6. The main color layer 30 and the pattern layer 40 are disposed on the same layer. The pattern layer 40 constitutes a predetermined pattern. The first side 401 of the pattern layer 40 is flush with the first side 301 of the main color layer 30, and the second side 402 of the pattern layer 40 is flush with the second side 302 of the main color layer 30. A bottom layer 60 is disposed on the first side 301 of the main color layer 30 and the first side 401 of the pattern layer 40 as shown in FIG. 7 to complement the flatness of the first side 301 of the main color layer 30 and the first side 401 of the pattern layer 40. A fingerprint sensor 10 is disposed on a side of the bottom later 60 that corresponds to the first side 301 of the main color layer 30 and the first side 401 of the pattern layer 40 as shown in FIG. 8. The fingerprint sensor 10 may be attached to the bottom layer 60 through an adhesive layer 11.

The step of disposing the main color layer 30 and the pattern layer 40 on the same layer may comprise following steps. In one embodiment, the main color layer 30 is disposed on a first side 201 of the cover 20, and then the pattern layer 40 is disposed in the orifices 31 of the main color layer 30 to constitute the predetermined pattern. In another embodiment, the pattern layer 40 is disposed on the first side 201 of the cover 20 first, and then the main color layer 30 is disposed beside the pattern layer 40. The main color layer 30 and the pattern layer 40 are disposed by coating, spraying, screen printing and so on.

In conclusion, the fingerprint sensing module as described makes the two sides of the main color layer 30 and the pattern later 40 to flush with each other by the change of the structure and the manufacturing ways. Thus, the capacitance variation during fingerprint sensing is consistent at both positions corresponding to the main color layer 30 and the pattern layer 40. Then the sensed fingerprint images reflect the real fingerprint images without being affected by the predetermined pattern presented by the pattern layer 40. At the same time, the thickness of the pattern layer 40 and the main color layer 30 are the same, so that the color saturation of the predetermined pattern is improved.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A patterned fingerprint sensing module comprising:
a fingerprint sensor having a sensing array to detect a fingerprint;
a cover disposed on a top of the fingerprint sensor corresponding to the sensing array;
a main color layer disposed between the cover and the fingerprint sensor and having a first side and a second side; and
a pattern layer disposed between the cover and the fingerprint sensor, disposed on the same layer with the main color layer, constituting a predetermined pattern and having a first side and a second side, wherein
a color of the main color layer is different from a color of the pattern layer, the first side of the main color layer is flush with the first side of the pattern layer, and the second side of the main color layer is flush with the second side of the pattern layer.

2. The patterned fingerprint sensing module as claimed in claim 1, wherein a difference between a dielectric constant of the pattern layer and a dielectric constant of the main color layer is between −2 and +2.

3. The patterned fingerprint sensing module as claimed in claim 1 further comprising a bottom layer disposed between the fingerprint sensor and the main color layer with the pattern layer.

4. The patterned fingerprint sensing module as claimed in claim 2 further comprising a bottom layer disposed between the fingerprint sensor and the main color layer with the pattern layer.

5. The patterned fingerprint sensing module as claimed in claim 1 further comprising an adhesive layer disposed between the fingerprint sensor and the main color layer with the pattern layer.

6. The patterned fingerprint sensing module as claimed in claim 2 further comprising an adhesive layer disposed between the fingerprint sensor and the main color layer with the pattern layer.

7. The patterned fingerprint sensing module as claimed in claim 3, wherein the cover is transparent or translucent.

8. The patterned fingerprint sensing module as claimed in claim 4, wherein the cover is transparent or translucent.

9. A manufacturing method of a patterned fingerprint sensing module comprising steps of:
providing a cover having a first side and a second side;
disposing a main color layer and a pattern layer on the first side of the cover, wherein the main color layer and the pattern layer are disposed on the same layer, the pattern layer constitutes a predetermined pattern, a first side of the main color layer is flush with a first side of the pattern layer, a second side of the main color layer is flush with a second side of the pattern layer, the second side of the main color layer and the second side of the pattern layer face to the first side of the cover; and
disposing a fingerprint sensor on the first side of the main color layer and the first side of the pattern layer.

10. The manufacturing method of a patterned fingerprint sensing module as claimed in claim 9, wherein the step of disposing the main color layer and the pattern layer comprises following steps;
disposing the main color layer on the first side of the cover with at least one orifice, wherein the at least one orifice constitutes the predetermined pattern; and
disposing the pattern layer in the at least one orifice.

11. The manufacturing method of a patterned fingerprint sensing module as claimed in claim 9, wherein the step of disposing the main color layer and the pattern layer comprises following steps;
disposing the pattern layer on the first side of the cover; and
disposing the main color layer beside the pattern layer.

12. The manufacturing method of a patterned fingerprint sensing module as claimed in claim 9, wherein a difference between a dielectric constant of the pattern layer and a dielectric constant of the main color layer is between −2 and +2.

13. The manufacturing method of a patterned fingerprint sensing module as claimed in claim 9, wherein disposing the fingerprint sensor comprises steps of:
disposing a bottom layer on the first side of the main color layer and the first side of the pattern layer; and
disposing the fingerprint sensor of a side of the bottom layer.

14. The manufacturing method of a patterned fingerprint sensing module as claimed in claim 10, wherein disposing the fingerprint sensor comprises steps of:
disposing a bottom layer on the first side of the main color layer and the first side of the pattern layer; and
disposing the fingerprint sensor of a side of the bottom layer.

15. The manufacturing method of a patterned fingerprint sensing module as claimed in claim 11, wherein disposing the fingerprint sensor comprises steps of:
disposing a bottom layer on the first side of the main color layer and the first side of the pattern layer; and
disposing the fingerprint sensor of a side of the bottom layer.

16. The manufacturing method of a patterned fingerprint sensing module as claimed in claim 9, wherein the fingerprint sensor is disposed on the first side of the main color layer and the first side of the pattern layer through an adhesive layer.

17. The manufacturing method of a patterned fingerprint sensing module as claimed in claim 10, wherein the fingerprint sensor is disposed on the first side of the main color layer and the first side of the pattern layer through an adhesive layer.

18. The manufacturing method of a patterned fingerprint sensing module as claimed in claim 11, wherein the fingerprint sensor is disposed on the first side of the main color layer and the first side of the pattern layer through an adhesive layer.

19. The manufacturing method of a patterned fingerprint sensing module as claimed in claim 13, wherein the fingerprint sensor is disposed on the side of bottom layer through an adhesive layer.

20. The manufacturing method of a patterned fingerprint sensing module as claimed in claim 14, wherein the fingerprint sensor is disposed on the side of bottom layer through an adhesive layer.
